(19) United States
(12) Patent Application Publication
(10) Pub. No.: US 2014/0183581 A1
(43) Pub. Date: Jul. 3, 2014

(54) LIGHT-EMITTING DEVICE AND MANUFACTURING METHOD THEREOF

(71) Applicant: EPISTAR CORPORATION, Hsinchu (TW)

(72) Inventors: Chi Hung Wu, Hsinchu (TW); Chen Ou, Hsinchu (TW); Chi Ling LEE, Hsinchu (TW); Wei Han WANG, Hsinchu (TW); Hui Tang SHEN, Hsinchu (TW); Yi Lin GUO, Hsinchu (TW); Hung Chih YANG, Hsinchu (TW)

(73) Assignee: EPISTAR CORPORATION, Hsinchu (TW)

(21) Appl. No.: 13/731,887

(22) Filed: Dec. 31, 2012

(51) Int. Cl. H01L 33/22

(52) U.S. Cl. CPC H01L 33/22
USPC 257/98; 438/29

(57) ABSTRACT

A light-emitting device comprises a substrate; a first semiconductor layer formed on the substrate; a light-emitting layer on the first semiconductor layer; and a second semiconductor layer having a rough surface formed on the light-emitting layer, wherein the rough surface comprises a plurality of cavities randomly distributed on the rough surface, and one of the plurality of cavities has a substantially hexagonal shape viewed from top and a curved sidewall viewed from cross-section.

### TECHNICAL FIELD

The application relates to a light-emitting device, and more particularly, to a light-emitting device comprising a semiconductor layer having a rough surface with a plurality of cavities randomly distributed on the rough surface, and the manufacturing method thereof.

### DESCRIPTION OF BACKGROUND ART

The light-emitting diode (LED) is a solid state semiconductor device. The structure of the LED comprises a p-type semiconductor layer, an n-type semiconductor layer, and a light-emitting layer formed between the p-type semiconductor layer and the n-type semiconductor layer. The light-emitting principle of the LED is the transformation of electrical energy to optical energy by applying an electrical current to the p-n junction to generate electrons and holes. Then, the LED emits a light when the electrons and the holes combine.

### SUMMARY OF THE APPLICATION

A light-emitting device comprises a substrate; a first semiconductor layer formed on the substrate; a light-emitting layer on the first semiconductor layer; and a second semiconductor layer having a rough surface formed on the light-emitting layer, wherein the rough surface comprises a plurality of cavities randomly distributed on the rough surface, and one of the plurality of cavities has a substantially hexagonal shape viewed from top and a curved sidewall viewed from cross-section.

A manufacturing method of a light-emitting device comprises providing a substrate; growing a first semiconductor layer comprising a first semiconductor material on the substrate and forming a first rough surface with a plurality of cavities during growing the first semiconductor layer; and treating the first rough surface of the first semiconductor layer with a reducing gas to form a second rough surface.

### BRIEF DESCRIPTION OF THE DRAWINGS

FIGS. 1-4 illustrate a manufacturing method of a light-emitting device in accordance with an embodiment of the present application;

FIG. 5 illustrates a perspective diagram of a light-emitting device before reducing gas treatment in accordance with an embodiment of the present application;

FIG. 6 illustrates a tilted SEM diagram of a light-emitting device before reducing gas treatment in accordance with an embodiment of the present application;

FIG. 7 illustrates a cross-sectional SEM diagram of a light-emitting device before reducing gas treatment in accordance with an embodiment of the present application;

FIG. 8 illustrates a perspective diagram of a light-emitting device after reducing gas treatment in accordance with an embodiment of the present application;

FIG. 9 illustrates a tilted SEM diagram of a light-emitting device after reducing gas treatment in accordance with an embodiment of the present application;

FIG. 10 illustrates a cross-sectional SEM diagram of a light-emitting device after reducing gas treatment in accordance with an embodiment of the present application;

FIG. 11 illustrates a cross-sectional diagram of a light-emitting device along line X-X′ of FIG. 5 before reducing gas treatment; and

FIG. 12 illustrates a cross-sectional diagram of a light-emitting device along line Y-Y′ of FIG. 8 after reducing gas treatment.

### DETAILED DESCRIPTION OF PREFERRED EMBODIMENTS

The embodiments of the application are illustrated in detail, and are plotted in the drawings. The same or the similar part is illustrated in the drawings and the specification with the same number.

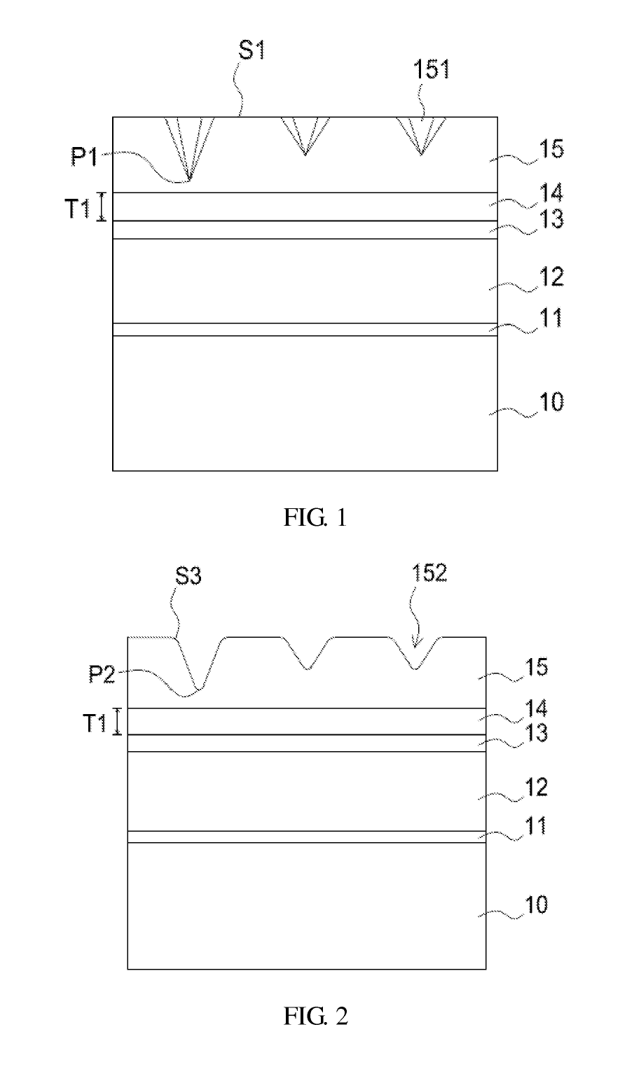

FIG. 1 to FIG. 3 illustrate a manufacturing method of a light-emitting device 1 in accordance with an embodiment of the present application. The manufacturing method comprises the following steps:

Step 1: providing a substrate 10, such as a sapphire substrate;

Step 2: forming a buffer layer 11, such as AlN buffer layer, on the substrate 10;

Step 3: forming a first semiconductor layer 12 on the buffer layer 11;

Step 4: forming a light-emitting layer 13 having a structure, such as InGaN-based multiple-quantum-well (MQW) structure, on the first semiconductor layer 12. In the embodiment, the material of the first semiconductor layer 12, the light-emitting layer 13 and the second semiconductor layer 15 comprise group III-VA compound semiconductor such as gallium nitride (GaN);

Step 5: forming a stop layer 14 on the light-emitting layer 13 in a reaction chamber under a reduced pressure environment, such as between 50 mbar and 350 mbar and at a temperature between 700° C. and 1200° C., and nitrogen (N₂) and ammonia (NH₃) are introduced into the reaction chamber to be a carrier gas, wherein the material of the stop layer 14 comprises AlₓGa₁₋ₓN, wherein 0<x<1, and a thickness T1 of the stop layer 14 is between 50 Å and 500 Å;

Step 6: forming a second semiconductor layer 15 having a second semiconductor material, such as p-type group II A-nitride semiconductor material, for example GaN, on the light-emitting layer 13 in the reaction chamber under a pressure between 100 mbar and 900 mbar and at a temperature between 700° C. and 1200° C., and nitrogen (N₂) and ammonia (NH₃) are introduced into the reaction chamber to be the carrier gas, wherein a polarity of the second semiconductor layer 15 is opposite to a polarity of the first semiconductor layer 12. The first semiconductor layer 12, the second semiconductor layer 15, or the light-emitting layer 13 may be grown in the reaction chamber by a known epitaxy method such as metallic-organic chemical vapor deposition (MOCVD) method, a molecular beam epitaxy (MBE) method, or a hydride vapor phase epitaxy (HVPE) method;

Step 7: forming a first rough surface 51 with a plurality of cavities 151 during growing the second semiconductor layer 15, wherein the cavity 151 comprises a polygonal pyramid shape, such as hexagonal-pyramid shape, in a perspective view;

Step 8: treating the first rough surface S1 of the second semiconductor layer 15 by a reducing gas, such as hydrogen gas (H₂), in the reaction chamber to form a second rough surface S3 under a pressure between 300 mbar and 700 mbar and at a temperature between 800° C. and 1250° C., and nitrogen (N₂) and ammonia (NH₃) are stopped being introduced into the reaction chamber, wherein the cavity 151 having a sharp corner shown in FIG. 1 is treated by the reducing gas to form a cavity 152 having a round corner as shown in FIG. 2. In the embodiment, the epitaxial growth surface of the second semiconductor layer 15 on the sapphire substrate is c-plane and Ga element rich. When the hydrogen gas (H₂) contacts the first rough surface S1 of the second semiconductor layer 15, the c-plane is more vulnerable than other planes, such as a-plane or m-plane. In other words, the second rough surface S3 comprises a crystal plane like a-plane or m-plane is less reactive with the reducing gas than c-plane. The stop layer 14 comprises a chemical property less reactive with the reducing gas than the second semiconductor layer 15, and the reducing gas decomposes the second semiconductor material of the second semiconductor layer 15 to a group IIIA element, such as Ga;

Step 9: nitrogenizing the second semiconductor layer 15 after treating the first rough surface S1 of the second semiconductor layer 15 by introducing a nitrogen-containing gas, such as NH₃, into the reaction chamber under a pressure between 100 mbar and 900 mbar and at a temperature between 700° C. and 1200° C., and nitrogen (N₂) and ammonia (NH₃) are introduced into the reaction chamber to be the carrier gas, wherein the group III A element, such as Ga, reacts with the nitrogen-containing gas, such as NH₃, to form the second semiconductor material of the second semiconductor layer 15, such as GaN, during the nitrogenizing step;

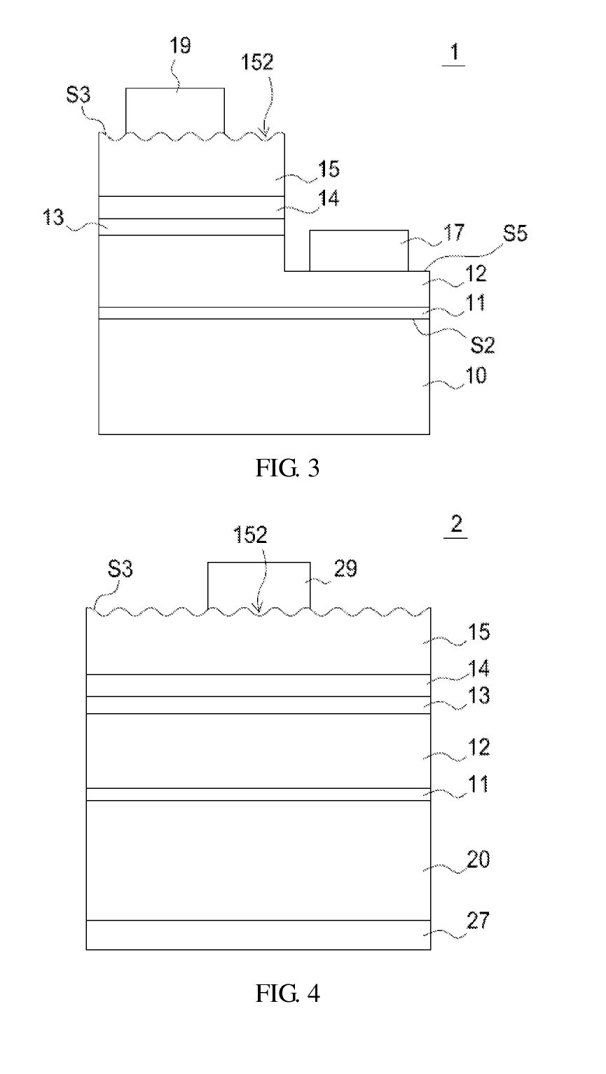

Step 10: forming a mesa to expose a top surface S5 of the first semiconductor layer 12 as shown in FIG. 3; and

Step 11: forming a first electrode 17 on the top surface S5 of the first semiconductor layer 12, and forming a second electrode 19 on the second rough surface S3 of the second semiconductor layer 15 to complete the horizontal-type light-emitting device 1 as shown in FIG. 3. The substrate 10 can be an insulating substrate, such as sapphire, GaN, AlN, ZnO, MgO, MgAl₂O₄, or glass. Another example of the embodiment for a vertical-type light-emitting device 2 is also disclosed in FIG. 4 by arranging a first electrode 27 and a second electrode 29 on opposite sides of a conductive substrate 20. The conductive substrate 20 comprises a conductive material, such as metal or semiconductor. As shown in FIG. 4, the major difference between the light-emitting device 1 and the light-emitting device 2 is that the first electrode 27 and the second electrode 29 of the light-emitting device 2 are on opposite sides of the conductive substrate 20, and the first electrode 17 and the second electrode 19 of the light-emitting device 1 are on the same sides of the substrate 10.

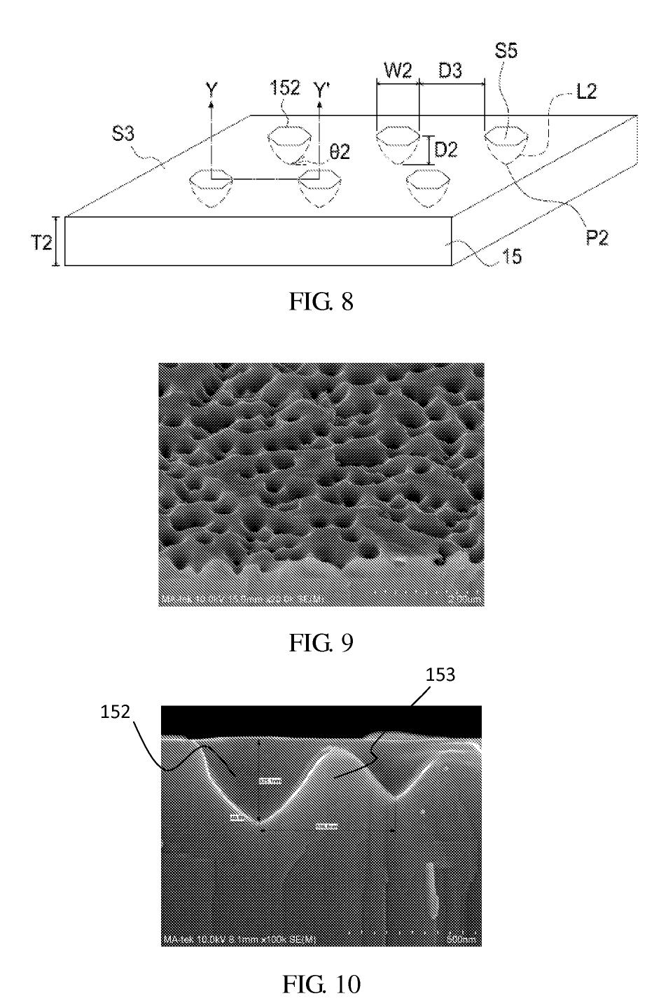

As shown in FIG. 3, the light-emitting device 1 comprises the substrate 10 having an epitaxial growth plane S2; the buffer layer 11 on the substrate 10; the first semiconductor layer 12 formed on the buffer layer 11; the light-emitting layer 13 on the first semiconductor layer 12; and the second semiconductor layer 15 having the second rough surface S3 formed on the light-emitting layer 13, wherein the second rough surface S3 comprises a plurality of cavities 152 randomly distributed on the second rough surface S3, and one of the plurality of cavities 152 has a substantially hexagonal shape viewed from top and a curved sidewall viewed from cross-section as shown in FIGS. 8-10. Here, a substantially hexagonal shape means the corner of the cavity 152 is round, but overall is hexagonal shape viewed from top. The light-emitting device 1 further comprises the stop layer 14 formed between the light-emitting layer 13 and the second semiconductor layer 15, wherein the stop layer 14 comprises a chemical property less reactive with the reducing gas than the second semiconductor layer 15.

During the epitaxial growth of the first semiconductor layer 12, the light-emitting layer 13, and the second semiconductor layer 15, some dislocation sites are formed, and the stop layer 14 helps to prevent the reducing gas from damaging the multiple-quantum-well (MQW) structure of the light-emitting layer 13 through the dislocation site.

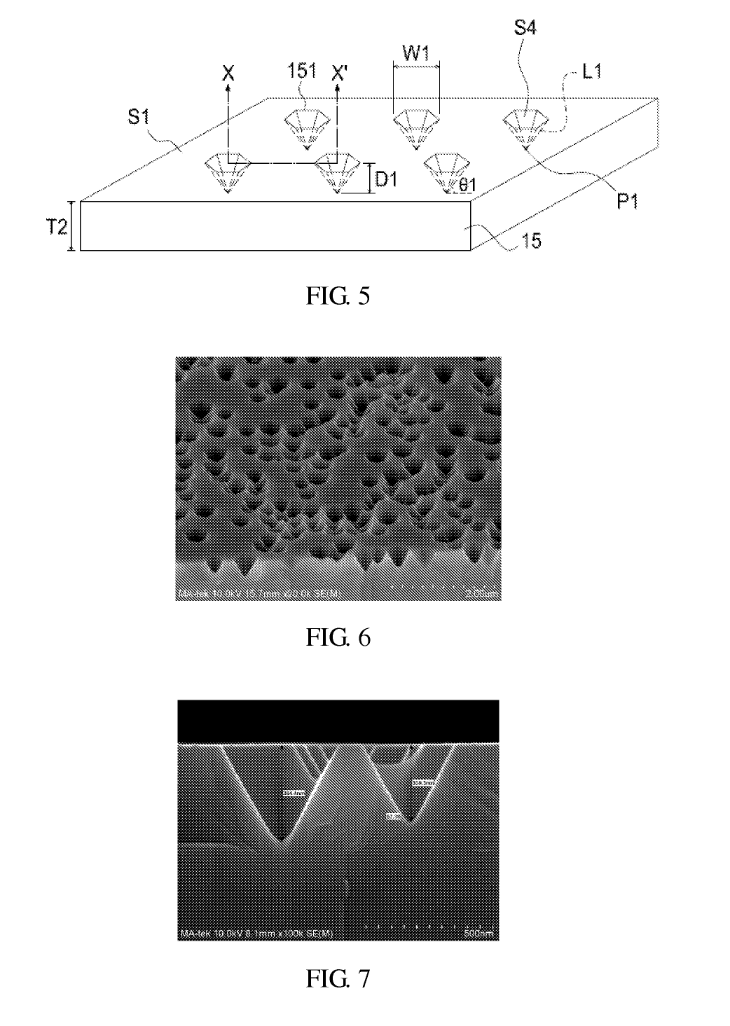

FIG. 5 illustrates a perspective diagram of the light-emitting device 1 or 2 before reducing gas treatment. FIG. 6 illustrates a tilted SEM diagram of the light-emitting device 1 or 2 before reducing gas treatment in accordance with an embodiment of the present application. FIG. 7 illustrates a cross-sectional SEM diagram of the light-emitting device 1 or 2 before reducing gas treatment in accordance with an embodiment of the present application. As shown in FIG. 5, the cavity 151 comprises a hexagonal shape viewed from top, a hexagonal-pyramid shape viewed from perspective and a plurality of inclined sidewalls S4. The inclined sidewall S4 is a triangular inclined surface and includes two inclined sides L1 viewed from cross-section. The inclined sidewalls S4 are connected to each other with the inclined side L1. The cavity 151 extends downward from the first rough surface S1 of the second nitride semiconductor layer 15 into the second nitride semiconductor layer 15 or into the light-emitting layer 13. Each of the plurality of cavities 151 comprises a deepest point P1 which is randomly distributed in the second nitride semiconductor layer 15. A depth D1 or a width W1 of one of the plurality of cavities 151 is different with that of another one of the plurality of cavities 151. In one embodiment, the thickness T2 of the second semiconductor layer 15 can be between 500 Å and 20000 Å, and the width W1 is approximately similar to or larger than the depth D1.

As shown in FIG. 5, an angle θ1 between the inclined side L1 and c-plane is between 10 and 75 degrees, preferably 57 degrees.

FIG. 8 illustrates a perspective diagram of the light-emitting device 1 or 2 after reducing gas treatment. FIG. 9 illustrates a tilted SEM diagram of the light-emitting device 1 or 2 after reducing gas treatment in accordance with an embodiment of the present application. FIG. 10 illustrates a cross-sectional SEM diagram of the light-emitting device 1 or 2 after reducing gas treatment in accordance with an embodiment of the present application. As shown in FIG. 8, the cavity 152 comprises a substantially hexagonal shape viewed from top, a cone shape viewed from perspective and a curved sidewall S5. The curved sidewall S5 surrounds the cavity 152 continuously, and comprises a curved edge L2 viewed from cross-section. The cavity 152 extends downward from the second rough surface S3 of the second nitride semiconductor layer 15 into the second nitride semiconductor layer 15 or into the light-emitting layer 13. Each of the plurality of cavities 152 comprises a deepest point P2 which is randomly distributed in the second nitride semiconductor layer 15 A depth D2 or a width W2 of one of the plurality of cavities 152 is different with that of another one of the plurality of cavities 152. The second rough surface S3 is substantially devoid of a flat plane parallel to the epitaxial growth plane S2 of the substrate 10. In one embodiment, 80% above of the second rough surface S3 is devoid of a plane, such as c-plane, parallel to the epitaxial growth plane S2 of the substrate 10, such as c-plane. The second rough surface S3 comprises the crystal plane like a-plane or m-plane, which are less reactive with the reducing gas than c-plane. In one embodiment, the width W2 is approximately similar to or larger than the depth D2. In one embodiment, the width W2 is approximately similar to the width W1 or the depth D2 is approximately similar to the depth D1.

As shown in FIG. 8, an angle θ2 between a tangent line (not shown) of the curved edge L2 and c-plane is between 10 and 75 degrees, preferably 41 degrees. The angle θ2 of the cavity 152 after reducing gas treatment is smaller than the angle θ1 of the cavity 151 before reducing gas treatment. In an embodiment of the present application, the angle θ2 of one of the plurality of cavities 152 can be different with that of another one of the plurality of cavities 152. Part of the plurality of cavities 152 are spaced apart from one another with a gap D3, wherein a surface of the gap D3 comprises a curved shape viewed from cross-section. Another part of the plurality of cavities 152 are directly connected with one another as shown in FIG. 9. As shown in FIG. 10, a protrusion 153 between any two of the cavities 152 comprises a curved shape viewed from cross-section. A bottom portion (not shown) of one of the plurality of cavities 152 comprises a curved shape viewed from cross-section. Optionally, a sidewall of one of the plurality of cavities comprises different inclined surfaces wherein a joint between the different inclined surfaces (not shown) is rounded.

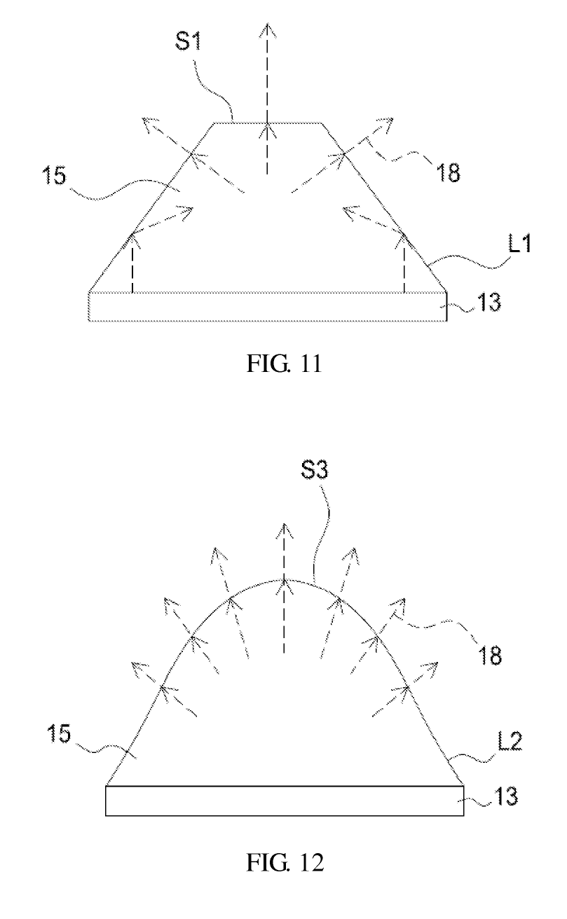

FIG. 11 illustrates a cross-sectional diagram of the light-emitting device 1 or 2 along line X-X′ of FIG. 5 before reducing gas treatment. In one embodiment, the second semiconductor layer 15 has a polarity opposite to that of the first semiconductor layer 12. For example, the second semiconductor layer 15 can be a p-type semiconductor layer and the first semiconductor layer 12 can be an n-type semiconductor layer. A light 18 is generated in a light emitting region (not shown) of the light-emitting layer 13 through recombination of holes injected from the p-type semiconductor layer and electrons injected from the n-type semiconductor layer. The light 18 emitted from the light-emitting layer 13 can be extracted to the outside of the light-emitting device 1 or 2 from the first rough surface S1 and the inclined sidewall L1 of the second semiconductor layer 15. However, the inclined sidewall L1 is an even surface, and part of the light 18 not within the critical angle of the second semiconductor layer 15 is totally reflected on the first rough surface S1 and the inclined sidewall L1. In addition, part of the light 18 is absorbed during repeated total reflection within the semiconductor layers of the light-emitting device 1 or 2, resulting in lower external quantum efficiency.

FIG. 12 illustrates a cross-sectional diagram of the light-emitting device 1 or 2 along line Y-Y′ of FIG. 8 after reducing gas treatment. The light 18 emitted from the light-emitting layer 13 can be extracted to the outside of the light-emitting device 1 or 2 from the second rough surface S3 and the curved sidewall L2. The second rough surface S3 is substantially devoid of the flat plane parallel to the epitaxial growth plane S2 of the substrate 10. The second rough surface S3 and the curved sidewall L2 reduce the possibility of total internal reflection. The light extraction efficiency of the light-emitting device 1 or 2 after reducing gas treatment is improved compared with that of the light-emitting device 1 or 2 before reducing gas treatment since the total reflection is reduced.

The principle and the efficiency of the present application illustrated by the embodiments above are not the limitation of the application. Any person having ordinary skill in the art can modify or change the aforementioned embodiments. Therefore, the protection range of the rights in the application will be listed as the following claims.

What is claimed is:

1. A manufacturing method of a light-emitting device, comprising:
providing a substrate;
growing a first semiconductor layer comprising a first semiconductor material on the substrate and forming a first rough surface with a plurality of cavities during growing the first semiconductor layer; and
treating the first rough surface of the first semiconductor layer with a reducing gas to form a second rough surface.

2. The manufacturing method according to claim 1, further comprising nitrogenizing the first semiconductor layer after treating the first rough surface of the first semiconductor layer by introducing a nitrogen-containing gas.

3. The manufacturing method according to claim 1, wherein the second rough surface comprises a crystal plane less reactive with the reducing gas than c-plane is.

4. The manufacturing method according to claim 1, wherein the substrate comprises sapphire, GaN, AlN, SiC, GaAs, GaP, Si, ZnO, MgO, MgAl₂O₄, or glass.

5. The manufacturing method according to claim 2, wherein the first semiconductor material comprises p-type group III A-nitride semiconductor material.

6. The manufacturing method according to claim 1, further comprising forming a second semiconductor layer between the substrate and the first semiconductor layer, and forming a light-emitting layer between the first semiconductor layer and the second semiconductor layer, wherein a polarity of the second semiconductor layer is opposite to a polarity of the first semiconductor layer.

7. The manufacturing method according to claim 6, further comprising forming a stop layer between the first semiconductor layer and the light-emitting layer, wherein the stop layer is less reactive with the reducing gas than the first semiconductor layer, and the material of the stop layer comprises AlₓGa₁₋ₓN, wherein 0<x<1.

8. The manufacturing method according to claim 7, wherein a thickness of the stop layer is between 50 Å and 500 Å.

9. The manufacturing method according to claim 1, wherein the reducing gas comprises hydrogen gas.

10. The manufacturing method according to claim 5, wherein the reducing gas decomposes a material of the first semiconductor layer to a group IIIA element.

11. The manufacturing method according to claim 10, wherein the group III A element reacts with the nitrogen-containing gas to form the first semiconductor material during the nitrogenizing step.

12. A light-emitting device, comprising:
a substrate;
a first semiconductor layer formed on the substrate;
a light-emitting layer on the first semiconductor layer; and
a second semiconductor layer having a rough surface formed on the light-emitting layer, wherein the rough surface comprises a plurality of cavities randomly distributed on the rough surface, and one of the plurality of cavities has a substantially hexagonal shape viewed from top and a curved sidewall viewed from cross-section.

13. The light-emitting device according to claim 12, wherein each of the plurality of cavities comprises a deepest point and the deepest points are randomly distributed in the second semiconductor layer.

14. The light-emitting device according to claim 12, further comprising a stop layer formed between the light-emitting layer and the second semiconductor layer, wherein the stop layer comprises a chemical property less reactive with a reducing gas than the second semiconductor layer, wherein the material of the stop layer comprises AlₓGa₁₋ₓN, wherein 0<x<1.

15. The light-emitting device according to claim 14, wherein a thickness of the stop layer is between 50 Å and 500 Å.

16. The light-emitting device according to claim 12, wherein the substrate comprising an epitaxial growth plane, and the rough surface is substantially devoid of a flat plane parallel to the epitaxial growth plane of the substrate.

17. The light-emitting device according to claim 12, wherein one of the plurality of cavities comprises a cone shape, and an angle between a tangent line of the curved sidewall and c-plane is between 10 and 75 degrees.

18. The light-emitting device according to claim 12, wherein the rough surface comprises a crystal plane less reactive with a reducing gas than c-plane.

19. The light-emitting device according to claim 12, wherein part of the plurality of cavities are spaced apart from one another with a gap, another part of the plurality of cavities are directly connected with one another, wherein the gap comprises a curved surface.

20. The light-emitting device according to claim 12, wherein a bottom portion of one of the plurality of cavities comprises a curved surface, and/or a sidewall of one of the plurality of cavities comprises different inclined surfaces.
